(19) United States
(12) Patent Application Publication
(10) Pub. No.: US 2026/0237558 A1
(43) Pub. Date: Aug. 13, 2026

(54) MULTILAYER ELECTRONIC COMPONENT AND MOUNTING BOARD THEREOF

(71) Applicant: SAMSUNG ELECTRO-MECHANICS CO., LTD., Suwon-si (KR)

(72) Inventors: Ho In JUN, Suwon-si (KR); Jung Eun LEE, Suwon-si (KR); Kyo Sik KIM, Suwon-si (KR)

(73) Assignee: SAMSUNG ELECTRO-MECHANICS CO., LTD., Suwon-si (KR)

(21) Appl. No.: 19/411,517

(22) Filed: Dec. 8, 2025

(30) Foreign Application Priority Data
Feb. 12, 2025 (KR) 10-2025-0018155

(51) Int. Cl. H01G 2/06; H01G 4/012; H01G 4/12; H01G 4/232; H01G 4/30

(52) U.S. Cl. CPC H01G 2/065; H01G 4/012; H01G 4/12; H01G 4/2325; H01G 4/30

(57) ABSTRACT

A multilayer electronic component includes a body having first and second surfaces opposing each other in a thickness direction, third and fourth surfaces connected to the first and second surfaces and opposing each other in a length direction, and fifth and sixth surfaces connected to the first to fourth surfaces and opposing each other in a width direction. The body includes a dielectric layer and multiple internal electrodes alternately arranged with the dielectric layer in the width direction. Each internal electrode includes a main portion and a lead-out portion extending from the main portion and exposed at the first surface. A slot is formed on the first surface and extends in the width direction, and a connection electrode is disposed within the slot and electrically connected to the lead-out portions to reduce overall thickness and improve connection stability when mounted on a circuit board.

### CROSS-REFERENCE TO RELATED APPLICATION(S)

This application claims the benefit of priority to Korean Patent Application No. 10-2025-0018155 filed on February 12, 2025 with the Korean Intellectual Property Office, the disclosure of which is incorporated herein by reference in its entirety.

### TECHNICAL FIELD

The present disclosure relates to a multilayer electronic component and a mounting board thereof.

Multilayer ceramic capacitors (MLCCs), a type of multilayer electronic component, are chip-shaped capacitors that are mounted on the printed circuit boards of various electronic products such as video devices of Liquid Crystal Displays (LCDs) and Plasma Display Panels (PDPs), computers, smartphones, and mobile phones to charge or discharge electricity therein or therefrom. MLCCs are used as components of various electronic devices due to their advantages of being small, having high capacity, and being easy to mount.

The recent trend toward miniaturization of various electronic products has led to demand for thinner MLCCs installed in electronic products. A typical MLCC consists of a ceramic body in which a dielectric layer and an internal electrode are stacked, and an external electrode positioned outside the ceramic body and connected to the internal electrode. Because the external electrode increases the thickness, length, and width of the MLCC, research into new MLCC types is necessary.

### SUMMARY

An aspect of the present disclosure is to provide a multilayer electronic component that is compact and exhibits excellent stability when mounted on a substrate.

According to an aspect of the present disclosure, a multilayer electronic component includes a body including a first surface and a second surface, opposing each other in a thickness direction, a third surface and a fourth surface connected to the first and second surfaces and opposing each other in a length direction, and a fifth surface and a sixth surface connected to the first to fourth surfaces and opposing each other in a width direction, the body including a dielectric layer and a plurality of internal electrodes alternately disposed with the dielectric layer in the width direction, the plurality of internal electrodes each including a main portion and a lead-out portion extending from the main portion and exposed to the first surface; a slot disposed on the first surface and extending in the width direction; and a connection electrode disposed within the slot and connected to the plurality of lead-out portions.

According to an aspect of the present disclosure, a multilayer electronic component includes a body including a first surface and a second surface, opposing each other in a thickness direction, a third surface and a fourth surface connected to the first and second surfaces and opposing each other in a length direction, and a fifth surface and a sixth surface connected to the first to fourth surfaces and opposing each other in a width direction, the body being provided with a slot disposed on the first surface and extending in the width direction; and a connection electrode disposed within the slot. The body includes a dielectric layer and a plurality of internal electrodes alternately disposed with the dielectric layer in the width direction, and the plurality of internal electrodes include a main portion and a lead-out portion extending from the main portion and exposed to an inner wall of the slot and in contact with the connection electrode.

According to an aspect of the present disclosure, a mounting board of a multilayer electronic component includes a printed circuit board including an electrode pad; a connection post positioned on the electrode pad; and the multilayer electronic component described above connected to the electrode pad. The connection post is positioned within the slot.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a perspective view schematically illustrating a multilayer electronic component according to an embodiment;

FIG. 2 is a schematic cross-sectional view taken along line I-I’ of FIG. 1, illustrating the planar structure of a first internal electrode;

FIG. 3 is a schematic cross-sectional view taken along line I-I’ of FIG. 1, illustrating the planar structure of a second internal electrode;

FIG. 4 is a schematic cross-sectional view taken along line II-II’ of FIG. 1;

FIG. 5 is a plan view of FIG. 1;

FIG. 6 is a perspective view schematically illustrating a multilayer electronic component according to another embodiment;

FIG. 7 is a schematic cross-sectional view taken along line III-III’ of FIG. 6, illustrating the planar structure of a first internal electrode;

FIG. 8 is a schematic cross-sectional view taken along line III-III’ of FIG. 6, illustrating the planar structure of a second internal electrode;

FIG. 9 is a plan view of FIG. 6;

FIGS. 10 and 11 are cross-sectional views schematically illustrating a mounting board of a multilayer electronic component according to an embodiment; and

FIGS. 12 and 13 are cross-sectional views schematically illustrating a board having a multilayer electronic component embedded therein according to an embodiment.

### DETAILED DESCRIPTION

Hereinafter, embodiments of the present disclosure will be described with reference to detailed embodiments and accompanying drawings. However, the embodiments of the present disclosure may be modified in many different forms, and the scope of the present disclosure is not limited to the embodiments described below. In addition, the embodiments of the present disclosure are provided to more completely describe the present disclosure to those skilled in the art. Therefore, the shapes and sizes of elements in the drawings may be exaggerated for clearer explanation, and elements indicated by the same reference numerals in the drawings are the same elements.

In addition, to clearly describe the present disclosure in the drawings, parts irrelevant to the description are omitted, and the size and thickness of each component illustrated in the drawings are arbitrarily illustrated for convenience of description, and thus, the present disclosure is not necessarily limited to the illustrated embodiment. Also, components having the same function within the scope of the same concept are described using the same reference numerals. Furthermore, throughout the specification, when a certain component is said to “include,” it means that it may further include other components without excluding other components unless otherwise stated.

In the drawing, the X-direction may be defined as the thickness (T) direction, the Y-direction as the length (L) direction, and the Z-direction as the width (W) direction.

### Multilayer Electronic Component

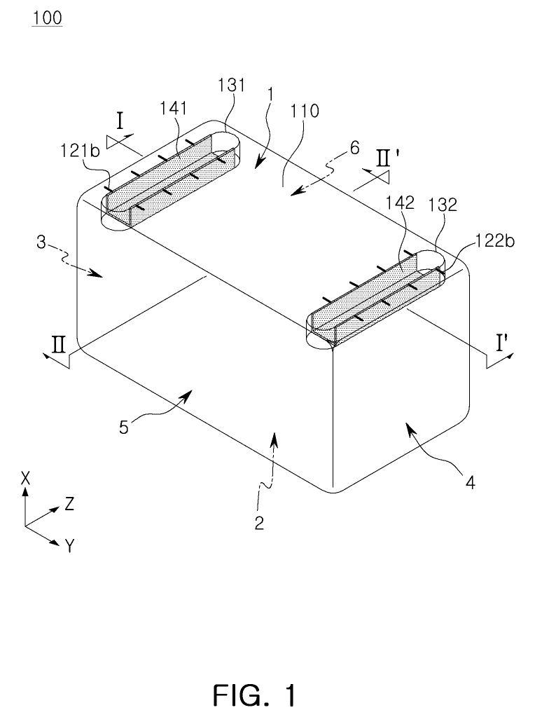

FIG. 1 is a perspective view schematically illustrating a multilayer electronic component according to an embodiment.

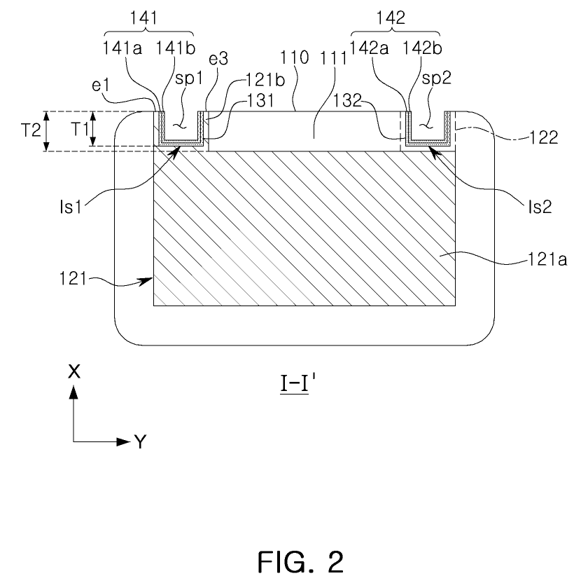

FIG. 2 is a schematic cross-sectional view taken along line I-I’ of FIG. 1, illustrating the planar structure of the first internal electrode.

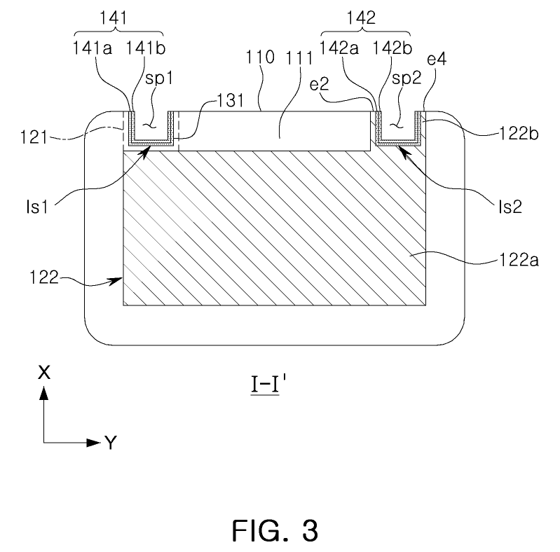

FIG. 3 is a schematic cross-sectional view taken along line I-I’ of FIG. 1, illustrating the planar structure of the second internal electrode.

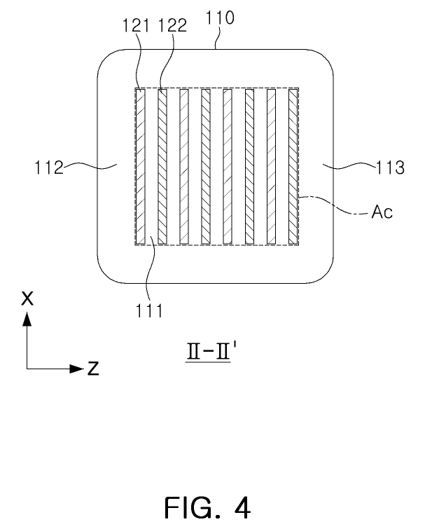

FIG. 4 is a schematic cross-sectional view taken along line II-II’ of FIG. 1.

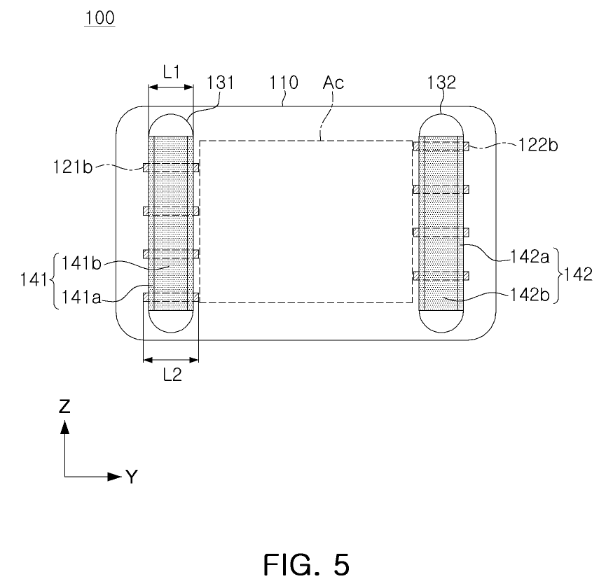

FIG. 5 is a plan view of FIG. 1.

Hereinafter, a multilayer electronic component 100 according to an embodiment will be described in detail with reference to FIGS. 1 through 5. Furthermore, while a multilayer ceramic capacitor is described as an example of a multilayer electronic component, the present disclosure is not limited thereto and may be applied to various multilayer electronic components, such as inductors, piezoelectric elements, varistors, or thermistors.

A multilayer electronic component 100 according to an embodiment may include a body 110, slots 131 and 132, and connection electrodes 141 and 142.

While there are no specific limitations on the detailed shape of the body 110, as illustrated, the body 110 may be formed in a hexahedral shape or a similar shape. Due to shrinkage of the ceramic powder contained in the body 110 during the firing process or due to a polishing process on the edges of the body 110, the body 110 may not be a perfectly straight hexahedral shape, but may have a substantially hexahedral shape.

The body 110 may have first and second surfaces 1 and 2 opposing each other in the thickness direction, third and fourth surfaces 3 and 4 connected to the first and second surfaces 1 and 2 and opposing each other in the length direction, and fifth and sixth surfaces 5 and 6 connected to the first to fourth surfaces 1, 2, 3 and 4 and opposing each other in the width direction.

The body 110 may include a dielectric layer 111 and a plurality of internal electrodes 121 and 122 disposed alternately with the dielectric layer 111 in the width direction. The plurality of dielectric layers 111 forming the body 110 are in a sintered state, and the boundaries between adjacent dielectric layers 111 may be so integrated that they are difficult to discern without a scanning electron microscope (SEM).

The size of the body 110 is not particularly limited, but the length of the body 110 may be greater than the width and thickness of the body 110. However, the present disclosure is not limited thereto, and the length of the body 110 may be smaller than the width of the body 110. The width of the body 110 may be smaller or larger than the thickness of the body 110, and this may vary depending on the specifications or characteristics of the multilayer electronic component 100.

The dielectric layer 111 may, for example, include a perovskite-type compound represented by ABO₃ as the main component thereof. The perovskite compound represented by ABO₃ may include at least one, for example, BaTiO₃, (Ba₁₋ₓCaₓ)TiO₃ (0<x<1), Ba(Ti_{1-y}Ca_{y})O₃ (0<y<1), (Ba₁₋ₓCaₓ)(Ti_{1-y}Zr_{y})O₃ (0<x<1, 0<y<1), Ba(Ti_{1-y}Zr_{y})O₃ (0<y<1), CaZrO₃ and (Ca₁₋ₓSrₓ)(Zr_{1-y}Ti_{y})O₃ (0<x≤0.5, 0<y≤0.5).

The average thickness of the dielectric layer 111 is not particularly limited. The average thickness of the dielectric layer 111 may be, for example, 0.1 μm to 20 μm, 0.1 μm to 10 μm, 0.1 μm to 5 μm, 0.1 μm to 2 μm, or 0.1 μm to 0.4 μm. In this case, the thickness of the dielectric layer 111 may refer to the size of the dielectric layer 111 in the stacking direction, for example, the width direction.

The plurality of internal electrodes 121 and 122 may include a first internal electrode 121 and a second internal electrode 122 disposed alternately with a dielectric layer 111 therebetween. The region of the body 110 where the first internal electrode 121 and the second internal electrode 122 overlap each other with the dielectric layer 111 therebetween may be defined as a capacitance forming portion (Ac).

The plurality of internal electrodes 121 and 122 may include main portions 121a and 122a and lead-out portions 121b and 122b extending from the main portions 121a and 122a and exposed to the first surface 1. The first internal electrode 121 may include a first main portion 121a and a first lead-out portion 121b extending from the first main portion 121a and exposed to the first surface 1, and the second internal electrode 122 may include a second main portion 122a and a second lead-out portion 122b extending from the second main portion 122a and exposed to the first surface 1.

The first main portion 121a and the second main portion 122a may overlap each other in the width direction. The first lead-out portion 121b may not overlap the second internal electrode 122 in the width direction, and the second lead-out portion 122b may not overlap the first internal electrode 121 in the width direction.

The shapes of the main portions 121a and 122a are not particularly limited, but may have a flat plate shape perpendicular to the width direction. The length size of the lead-out portions 121b and 122b may be smaller than the length size of the main portions 121a and 122a. While FIGS. 3 and 4 illustrate a structure in which the length size of the lead-out portions 121b and 122b is constant along the thickness direction, the present disclosure is not limited thereto. For example, the length size of the lead-out portions 121b and 122b may gradually decrease or increase from the main portions 121a and 122a toward the first surface 1.

At least one of the plurality of internal electrodes 121 and 122 may include of at least one of Ni, Cu, Pd, Ag, Au, Pt, Sn, W, Ti, and alloys thereof, in detail, At least one of the plurality of internal electrodes 121 and 122 may include Ni, but the present disclosure is not limited thereto.

The average thickness of the plurality of internal electrodes 121 and 122 is not particularly limited. The average thickness of the plurality of internal electrodes 121 and 122 may be, for example, 0.1 μm to 3.0 μm, 0.1 μm to 1.0 μm, or 0.1 μm to 0.4 μm.

The average thickness of the dielectric layer 111 and the average thickness of the internal electrodes 121 and 122 may be measured by scanning the width and thickness-direction cross-section (W-T cross-section) of the multilayer electronic component 100 using a scanning electron microscope (SEM) at 10,000x magnification. In more detail, the average thickness of the dielectric layer 111 may be measured by measuring the thickness at multiple points on a single dielectric layer 111, for example, five equally spaced points in the X-direction, and then taking the average value. Additionally, the average thickness of the internal electrodes 121 and 122 may be measured by measuring the thickness at multiple points on a single internal electrode 121 or 122, for example, at five equally spaced points in the X-direction, and then taking the average value. The five equally spaced points may be designated in the capacitance forming portion (Ac). Furthermore, by performing the measurement of these average values for each of the ten dielectric layers 111 and ten internal electrodes 121 and 122, and then taking the average values, the average thickness of the dielectric layer 111 and the average thickness of the internal electrodes 121 and 122 may be more generalized.

The body 110 may include cover portions 112 and 113 positioned on opposite sides of the capacitance forming portion (Ac), facing each other in the width direction. The cover portions 112 and 113 may have a similar configuration to the dielectric layer 111, except that they do not include the internal electrodes.

The average thickness of the cover portions 112 and 113 is not particularly limited. The average thickness of the cover portions 112 and 113 may be, for example, 150 μm or less, 100 μm or less, 30 μm or less, or 20 μm or less. The average thickness of the cover portions 112 and 113 may be, for example, 5 μm or more, 10 μm or more, or 30 μm or more. In this case, the average thickness of the cover portions 112 and 113 refers to the average thickness of each of the first cover portion 112 and the second cover portion 113. The average thickness of the cover portions 112 and 113 may be an average value of sizes in the width direction measured at five equally spaced points in the width direction and thickness direction cross-section of the multilayer electronic component 100.

Slots 131 and 132 may be positioned on the first surface 1 of the body 110 and extend in the width direction. Slots 131 and 132 may extend from the first surface 1 into the interior of the body 110 and may be positioned spaced apart from the main portions 121a and 122a. Slots 131 and 132 may be open to the first surface 1, and a plurality of lead-out portions 121b and 122b may be exposed through the inner walls of the slots 131 and 132.

Slots 131 and 132 may include a first slot 131 that exposes a plurality of first lead-out portions 121b, and a second slot 132 that is positioned spaced apart from the first slot 131 in the length direction and exposes a plurality of second lead-out portions 122b.

The shape of the slots 131 and 132 is not particularly limited. The slots 131 and 132 may have a rectangular or rounded rectangular shape in which the size thereof in the width direction is larger than the size in the length direction in the planar shape viewed in the thickness direction. The slots 131 and 132 may be disposed spaced apart from the fifth and sixth surfaces 5 and 6.

The size L1 of the slot in the length direction may be smaller than the size L2 of the lead-out portion in the length direction, and the size T1 of the slot in the thickness direction may be smaller than the size T2 of the lead-out portion in the thickness direction.

The connection electrodes 141 and 142 may be disposed within the slots 131 and 132 and connected to a plurality of lead-out portions 121b and 122b. For example, a plurality of lead-out portions 121b and 122b may contact connection electrodes 141 and 142 on the inner walls of slots 131 and 132. The connection electrodes 141 and 142 may serve as terminals for mounting the multilayer electronic component 100 on a printed circuit board.

The connection electrodes 141 and 142 may include a first connection electrode 141 disposed in the first slot 131 and connected to the first internal electrode 121, and a second connection electrode 142 disposed in the second slot 132 and connected to the second internal electrode 122.

External electrodes of the related art have the problem of increasing the thickness, length, and width of the multilayer electronic component because they are formed on the outside of the body. In contrast, in the multilayer electronic component 100 according to an embodiment of the present disclosure, the volume of the multilayer electronic component 100 may be reduced by including slots 131 and 132 and connection electrodes 141 and 142 instead of external electrodes of the related art, which allows for miniaturization and thinning of the multilayer electronic component 100.

For thinning of the multilayer electronic component 100, the connection electrodes 141 and 142 may be positioned within the slots 131 and 132 so as not to protrude further outward than the first surface 1. For example, the outermost surfaces of the multilayer electronic component 100 in the thickness direction may be the first surface 1 and/or the second surface 2.

In an embodiment, empty spaces sp1 and sp2 may be present within the slots 131 and 132, extending in the width direction and exposed to the first surface 1. The empty spaces sp1 and sp2 may provide a space capable of accommodating the electrode structure of the printed circuit board on which the multilayer electronic component 100 is mounted. The electrode structure may refer to a metal layer within the printed circuit board, an electrode pad and/or solder positioned on the printed circuit board. This may improve stability when mounting the multilayer electronic component 100 on the printed circuit board and reduce the volume occupied by the multilayer electronic component 100.

It is sufficient that the slots 131 and 132 be disposed to expose the plurality of lead portions 121b and 122b. However, in an embodiment, the slots 131 and 132 may extend between opposite length ends of the lead-out portions 121b and 122b, such that the lead-out portions 121b and 122b may have a plurality of exposed ends e1, e2, e3 and e4 that are divided from each other by the slots 131 and 132.

For example, the first slot 131 extends between opposite side ends in the length direction of the first lead-out portion 121b, and the first lead-out portion 121b may have a plurality of first exposed ends e1 and e3 that are divided from each other by the first slot 131, and the second slot 132 extends between opposite side ends in the length direction of the second lead-out portion 122b, and the second lead-out portion 122b may have a plurality of second exposed ends e2 and e4 that are divided from each other by the second slot 132.

The slots 131 and 132 extend between the opposite length ends of the lead-out portions 121b and 122b, thereby providing sufficient contact area between the internal electrodes 121 and 122 and the connection electrodes 141 and 142.

Referring to FIGS. 2 and 3, the slots 131 and 132 may include both side surfaces opposing each other in the length direction and bottom surfaces ls1 and ls2 facing the main portions 121a and 122a and connecting the side surfaces. For example, the connection electrodes 141 and 142 may be disposed continuously on the side surfaces and bottom surfaces ls1 and ls2. For example, the lead-out portions 121b and 122b may be exposed to the side surfaces and bottom surfaces ls1 and ls2 of the slots 131 and 132. This may enhance the contact area between the internal electrodes 121 and 122 and the connection electrodes 141 and 142.

The connection electrodes 141 and 142 may include, for example, Ni electrode layers 141a and 142a that contact a plurality of lead-out portions 121b and 122b and Sn electrode layers 141b and 142b that are disposed on the Ni electrode layers 141a and 142a. The Ni electrode layers 141a and 142a may be disposed continuously on both side surfaces and bottom surfaces ls1 and ls2 of the slots 131 and 132 to contact the plurality of lead-out portions 121b and 122b, and the Sn electrode layers 141b and 142b may be disposed on the Ni electrode layers 141a and 142a to contact an electrode structure of a printed circuit board.

The Ni electrode layers 141a and 142a and the Sn electrode layers 141b and 142b may be thin-film electrode layers formed using, for example, electrolytic plating, electroless plating, physical vapor deposition (PVD), chemical vapor deposition (CVD), and/or the like.

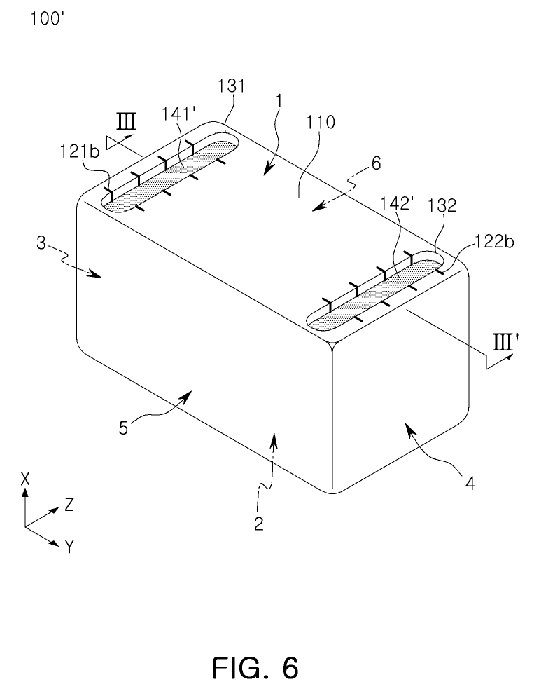

FIG. 6 is a perspective view schematically illustrating a multilayer electronic component according to another embodiment.

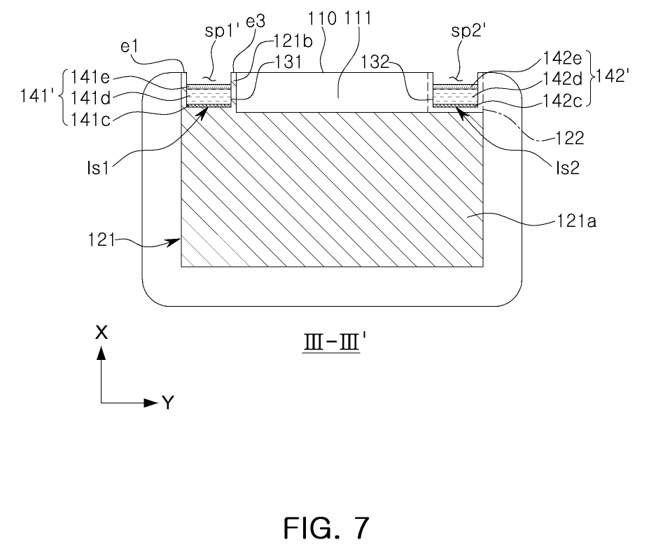

FIG. 7 is a schematic cross-sectional view taken along line III-III’ of FIG. 6, illustrating the planar structure of the first internal electrode.

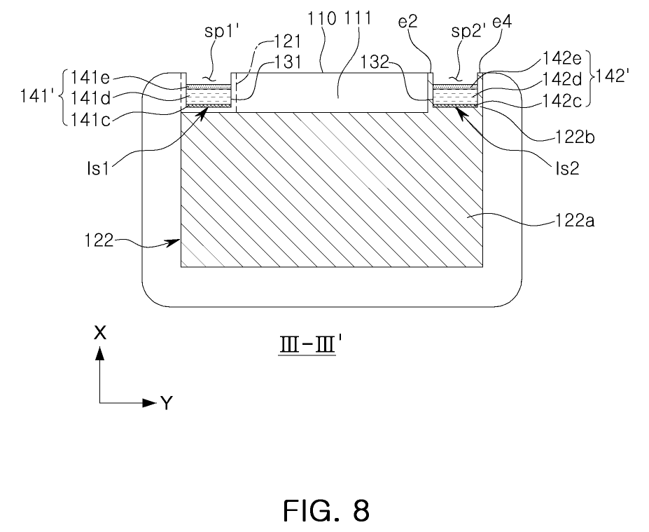

FIG. 8 is a schematic cross-sectional view taken along line III-III’ of FIG. 6, illustrating the planar structure of the second internal electrode.

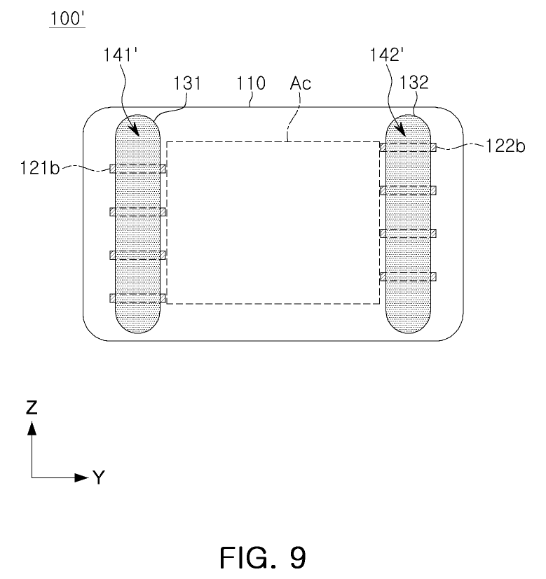

FIG. 9 is a plan view of FIG. 6.

Hereinafter, a multilayer electronic component 100’ according to another embodiment will be described with reference to FIGS. 6 to 9. For configurations identical or similar to those of the multilayer electronic component 100 described in FIGS. 1 to 5, identical or similar reference numerals are used, and duplicate descriptions will be omitted.

The multilayer electronic component 100’ may include connection electrodes 141’ and 142’ positioned within slots 131 and 132 and connected to a plurality of lead-out portions 121b and 122b. The connection electrodes 141’ and 142’ may include a first connection electrode 141’ connected to a plurality of first lead-out portions 121b and a second connection electrode 142’ connected to a plurality of second lead-out portions 122b.

The connection electrodes 141’ and 142’ may include first conductive pillars 141d and 142d that fill portions of the slots 131 and 132 and conductive joints 141e and 142e that are disposed between the conductive pillars 141d and 142d and the first surface 1. Seed layers 141c and 142c may be disposed between the conductive pillars 141d and 142d and the bottom surfaces ls1 and ls2 of the slots 131 and 132.

For example, the first connection electrode 141’ may include a first seed layer 141c disposed on the bottom surface ls1 of the first slot 131, a first conductive pillar 141d disposed on the first seed layer 141c, and a first conductive joint 141e disposed on the first conductive pillar 141d. The second connection electrode 142’ may include a second seed layer 142c disposed on the bottom surface ls2 of the second slot 132, a second conductive pillar 142d disposed on the second seed layer 142c, and a second conductive joint 142e disposed on the second conductive pillar 142d.

The connection electrodes 141’ and 142’ have a shape corresponding to the slots 131 and 132 and may fill portions of the slots 131 and 132. Within the slots 131 and 132, empty spaces sp1’ and sp2’ extending in the width direction and exposed to the first surface 1 may be present. The empty spaces sp1’ and sp2’ may be disposed between the first surface 1 and the connection electrodes 141’ and 142’.

The seed layers 141c and 142c may include, for example, Ni and/or Cu. The seed layers 141c and 142c may be thin film electrode layers formed using, for example, electrolytic plating, electroless plating, physical vapor deposition (PVD), and/or chemical vapor deposition (CVD). Although the drawing illustrates a structure in which the seed layers 141c and 142c are positioned only between the bottom surfaces ls1 and ls2 of the slots 131 and 132 and the lower surfaces of the conductive pillars 141d and 142d, the present disclosure is not limited thereto, and the seed layers 141c and 142c may also be positioned to extend between the side surfaces of the conductive pillars 141d and 142d and the side ends of the lead-out portions 121b and 122b.

The conductive pillars 141d and 142d may include, for example, Cu. The conductive pillars 141d and 142d may be formed using an electrolytic plating method, or the like. The conductive pillars 141d and 142d may have a columnar shape corresponding to that of the slots 131 and 132.

The conductive joints 141e and 142e may include, for example, Sn. The conductive joints 141e and 142e may be solder or Sn plating layers. The conductive joints 141e and 142e may serve to physically/electrically connect the connection electrodes 141’ and 142’ to the electrode structures of the printed circuit board.

### Method of Manufacturing Multilayer Electronic Component

Hereinafter, an example of a method of forming a multilayer electronic component 100, 100’ is described. However, the method of manufacturing the multilayer electronic components 100 and 100’ is not limited to this example.

First, a ceramic powder for forming a dielectric layer 111 is prepared. The ceramic powder may be a perovskite compound powder represented by ABO₃. The ceramic powder may include at least one of, for example, BaTiO₃, (Ba₁₋ₓCaₓ)TiO₃ (0<x<1), Ba(Ti_{1-y}Ca_{y})O₃ (0<y<1), (Ba₁₋ₓCaₓ)(Ti_{1-y}Zr_{y})O₃ (0<x<1, 0<y<1), Ba(Ti_{1-y}Zr_{y})O₃ (0<y<1), CaZrO₃, and (Ca₁₋ₓSrₓ)(Zr₁₋_{y}Ti_{y})O₃ (0<x≤0.5, 0<y≤0.5). The BaTiO₃ powder may be synthesized, for example, by reacting a titanium raw material such as titanium dioxide with a barium raw material such as barium carbonate. Methods for synthesizing the ceramic powder include, for example, a solid-state method, a sol-gel method, a hydrothermal synthesis method, and the like, but the present disclosure is not limited thereto. Next, the prepared ceramic powder is dried and ground, and then mixed with an organic solvent such as ethanol and a binder such as polyvinyl butyral to prepare a ceramic slurry. The ceramic slurry is applied to a carrier film and dried to prepare a ceramic green sheet.

Next, a conductive paste for internal electrodes, including metal powder, a binder, an organic solvent and the like, is printed on the ceramic green sheet to a predetermined thickness using a screen printing method, a gravure printing method or the like, thereby forming an internal electrode pattern.

Thereafter, the ceramic green sheet with the internal electrode pattern printed thereon is peeled from the carrier film, and then, a predetermined number of ceramic green sheets with the internal electrode pattern printed thereon are laminated and pressed together to form a ceramic laminate. A predetermined number of ceramic green sheets without the internal electrode pattern may be laminated on the upper and lower portions of the ceramic laminate to form cover portions 112 and 113 after firing. The ceramic laminate is then cut to a predetermined chip size, and the cut chips are fired to form the body 110. The lead-out portions 121b and 122b of the internal electrodes 121 and 122 may be exposed on the first surface 1 of the body 110. The firing may be performed, for example, in a 1.0%H₂/99.0%N₂ to 3.5%H₂/96.5%N₂ (H₂O/H₂/N₂ atmosphere), at a temperature of 1000°C to 1400°C for 1 to 3 hours.

Next, the portions of the first surface 1 to which the lead-out portions 121b and 122b are exposed may be machined using an end mill to form slots 131 and 132. This allows the lead-out portions 121b and 122b to be exposed not only on the first surface 1 but also on the inner walls of the slots 131 and 132.

Next, connection electrodes 141 and 142 may be formed by sequentially forming Ni electrode layers 141a and 142a and Sn electrode layers 141b and 142b inside the slots 131 132 using an electrolytic plating method, an electroless plating method, PVD, CVD and/or the like, thereby forming a multilayer electronic component 100.

Alternatively, seed layers 141c and 142c may be formed within the slots 131 and 132 using electrolytic plating, electroless plating, PVD, CVD, and/or the like, conductive pillars 141d and 142d may be formed on the seed layers 141c and 142c, and then connection electrodes 141’ and 142’ may be formed by forming a Sn plating layer on the conductive pillars 141d and 142d or filling with solder to form conductive joint 141e, 142e. This may form a multilayer electronic component 100’.

### Mounting Board of Multilayer Electronic Component

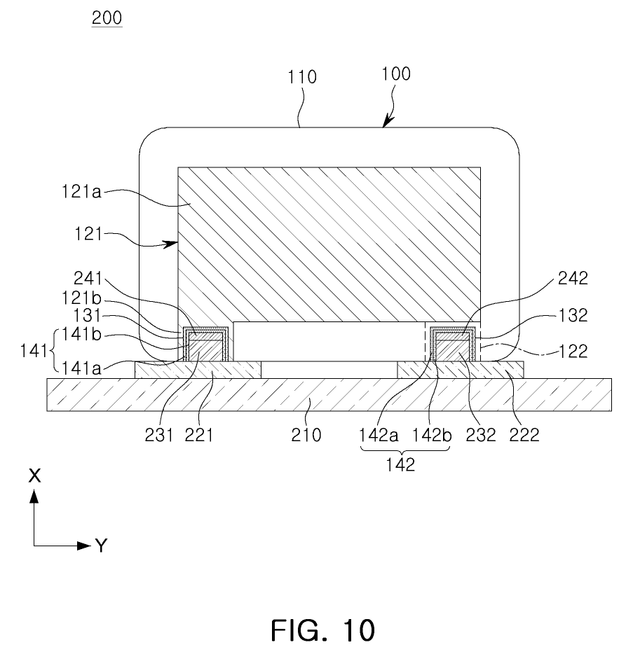

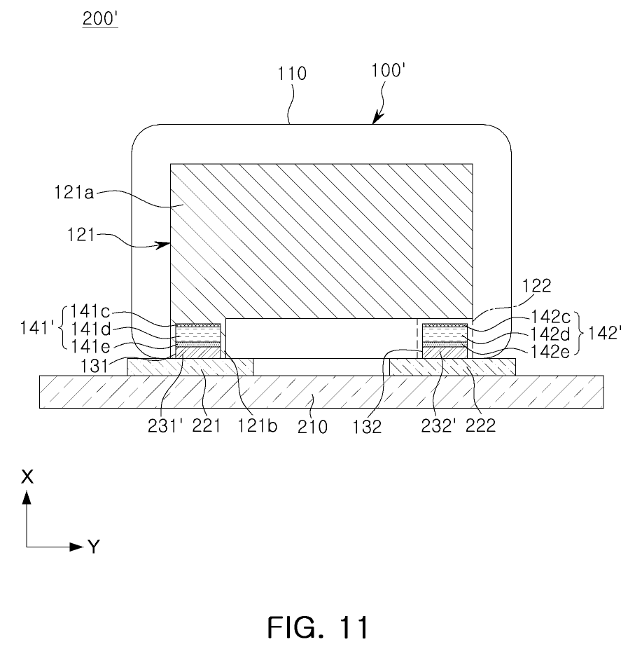

FIGS. 10 and 11 are schematic cross-sectional views illustrating a mounting board of a multilayer electronic component according to an embodiment.

Hereinafter, mounting boards 200 and 200’ for a multilayer electronic component according to embodiments will be described with reference to FIGS. 10 and 11. Components identical or similar to those of the multilayer electronic components 100 and 100’ described in FIGS. 1 to 9 are designated by the same or similar reference numerals, and redundant descriptions are omitted.

Referring to FIG. 10, a mounting board 200 for a multilayer electronic component may include a printed circuit board 210 including electrode pads 221 and 222, connection posts 231 and 232 disposed on the electrode pads 221 and 222, and a multilayer electronic component 100 connected to the electrode pads 221 and 222.

The printed circuit board 210 may include, for example, a resin such as glass epoxy or a ceramic such as glass ceramic. The printed circuit board 210 may have a form in which multiple insulating layers are stacked, for example. The printed circuit board 210 may include a first electrode pad 221 connected to a first connection electrode 141 and a second electrode pad 222 connected to a second connection electrode 142.

According to an embodiment, connection posts 231 and 232 may be disposed within slots 131 and 132. For example, the first connection post 231 may be coupled to the first slot 131, and the second connection post 232 may be coupled to the second slot 132. For example, the first connection post 231 may be inserted into a space provided within the first slot 131, and the second connection post 232 may be inserted into a space provided within the second slot 132.

Therefore, the volume required to mount the multilayer electronic component 100 on the printed circuit board 210 may be reduced, and the multilayer electronic component 100 may be stably mounted on the printed circuit board 210.

Solder portions 241 and 242 may be disposed on the upper surfaces of the connection posts 231 and 232. The solder portions 241 and 242 may be disposed between the connection posts 231 and 232 and the connection electrodes 141 and 142 to physically/electrically connect the same. Although the drawing illustrates a structure in which the solder portions 241 and 242 are disposed only between the upper surfaces of the connection posts 231 and 232 and the connection electrodes 141 and 142, the present disclosure is not limited thereto, and the solder portions 241 and 242 may be disposed to extend to the boundary between the side surfaces of the connection posts 231 and 232 and the connection electrodes 141 and 142.

The connection posts 231 and 232 may be formed using electrolytic plating, or the like, and the solder portions 241 and 242 may be formed by forming a solder cap shape on the upper surfaces of the connection posts 231 and 232 and then using a reflow process.

Referring to FIG. 11, a mounting board 200’for a multilayer electronic component may include a printed circuit board 210 including electrode pads 221 and 222, connection posts 231’ and 232’ disposed on the electrode pads 221 and 222, and a multilayer electronic component 100’ connected to the electrode pads 221 and 222.

According to an embodiment, the connection posts 231’ and 232’ may be disposed within the slots 131 and 132. For example, the first connection post 231’ may be coupled to the first slot 131, and the second connection post 232’ may be coupled to the second slot 132. For example, the first connection post 231’ may be inserted into a space provided within the first slot 131, and the second connection post 232’ may be inserted into a space provided within the second slot 132.

The conductive pillars 141d and 142d and the connection posts 231’ and 232’ may be physically/electrically connected to each other via conductive joints 141e and 142e. Although the drawing shows a structure in which the conductive joints 141e and 142e are disposed only between the lower surfaces of the conductive pillars 141d and 142d and the upper surfaces of the connection posts 231’ and 232’, the present disclosure is not limited thereto, and the conductive joints 141e and 142e may be disposed by extending to the boundary surface between the side surfaces of the conductive pillars 231 and 232 and the connection electrodes 141’ and 142’ and/or the boundary surface between the side surfaces of the connection posts 231’ and 232’ and the connection electrodes 141’ and 142’.

### Board Having Multilayer Electronic Component Embedded Therein

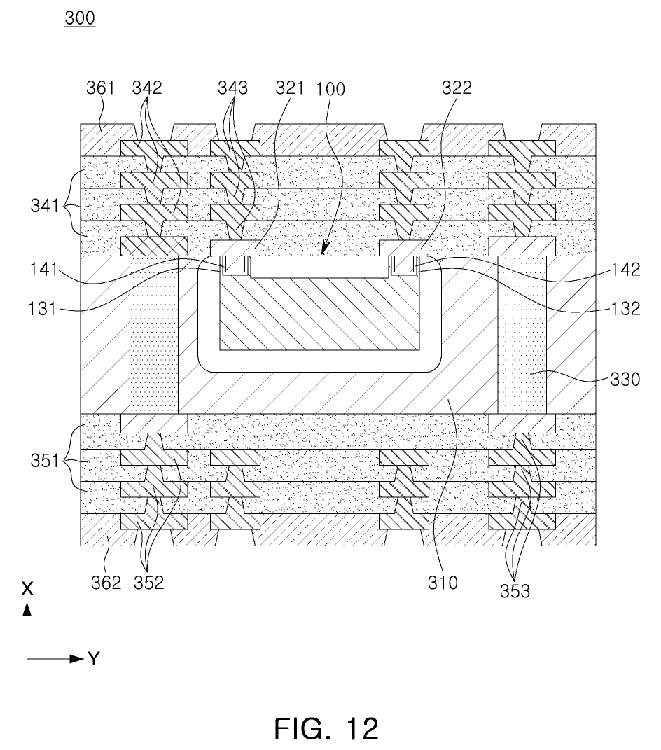

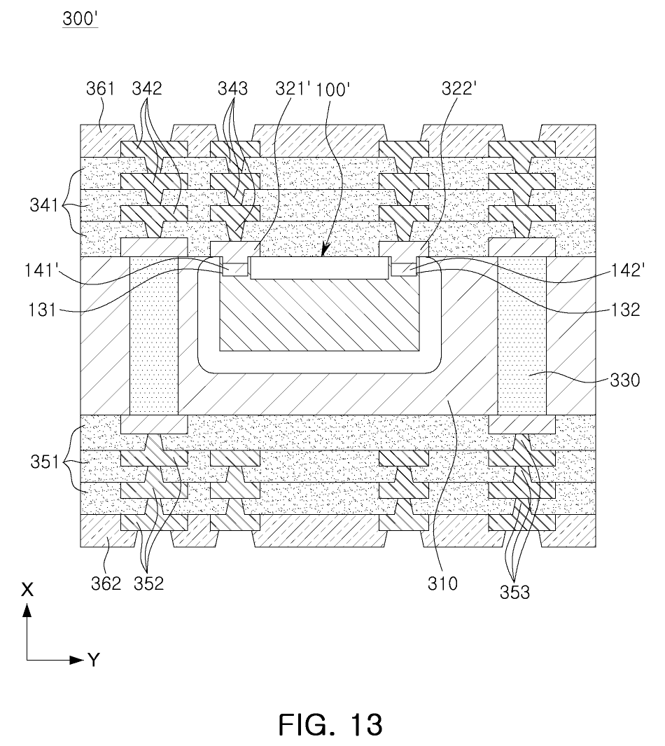

FIGS. 12 and 13 are schematic cross-sectional views illustrating a board having a multilayer electronic component embedded therein according to an embodiment.

Hereinafter, boards 300 and 300’ having a multilayer electronic component embedded therein according to embodiments will be described with reference to FIGS. 12 and 13. Components identical or similar to those of the multilayer electronic components 100 and 100’ described in FIGS. 1 to 9 will be designated by the same or similar reference numerals, and duplicate descriptions will be omitted.

Referring to FIG. 12, the board 300 having a multilayer electronic component embedded therein may include a core layer 310, a multilayer electronic component 100 embedded within the core layer 310, and metal layers 321 and 322 disposed on the upper surface of the core layer 310.

The slots 131 and 132 of the multilayer electronic component 100 may be exposed to the upper surface of the core layer 310. The first metal layer 321 may extend into the first slot 131 and be connected to the first connection electrode 141, and the second metal layer 322 may extend into the second slot 132 and be connected to the second connection electrode 142.

When the metal layers 321 and 322 are formed on the core layer 310 in which the multilayer electronic component 100 is embedded, using a plating or deposition method, portions of the metal layers 321 and 322 may extend into the slots 131 and 132 exposed to the upper surface of the core layer 310 and be disposed. For example, metal layers 321 and 322 may be formed within the slots 131 and 132 without a separate process, thereby connecting the metal layers 321 and 322 to the connection electrodes 141 and 142.

Therefore, the volume occupied by the multilayer electronic component 100 may be reduced and the multilayer electronic component 100 may be stably mounted within the board 300 having a multilayer electronic component embedded therein.

Referring to FIG. 13, a board 300’ having a multilayer electronic component embedded therein may include a core layer 310, a multilayer electronic component 100’ embedded within the core layer 310, and metal layers 321’ and 322’ disposed on the upper surface of the core layer 310.

The first metal layer 321’ may extend into the first slot 131 and be connected to the first connection electrode 141’, and the second metal layer 322’ may extend into the second slot 132 and be connected to the second connection electrode 142’.

As described above, when the metal layers 321’ and 322’ are formed on the core layer 310 containing the multilayer electronic component 100’ using a plating or deposition method, portions of the metal layers 321’ and 322’ may extend into the slots 131 and 132 exposed on the upper surface of the core layer 310 and be disposed therein. For example, metal layers 321’ and 322’ may be formed within the slots 131 and 132 without a separate process, thereby allowing the metal layers 321’ and 322’ to be connected to the connection electrodes 141’ and 142’.

The core layer 310 may include an insulating material and may be composed of multiple layers. The insulating material may include a thermosetting resin such as epoxy resin, a thermoplastic resin such as polyimide, or a material including such a resin together with inorganic fillers, organic fillers, and/or glass fibers (glass cloth, and/or glass fabric). The insulating material may include a photosensitive material and/or a non-photosensitive material. For example, insulating materials such as Solder Resist (SR), Ajinomoto Build-up Film (ABF), FR-4, Bismaleimide Triazine (BT), Prepreg (PPG), Resin Coated Copper (RCC), and Copper Clad Laminate (CCL) may be used, but are not limited thereto, and other polymeric materials may also be used. Meanwhile, the core layer 310 may also include glass. The glass may include, for example, pure silicon dioxide (approximately 100% SiO₂), soda-lime glass, borosilicate glass, aluminosilicate glass, or the like. However, the present disclosure is not limited thereto, and alternative glass materials such as fluorine glass, phosphate glass, and chalcogenide glass may also be used as materials. The core layer 310 may include, for example, plate glass, and may be, for example, a glass core.

The metal layers 321 and 322 may include a metal material such as Cu, Ni, Al, or the like, but the present disclosure is not limited thereto.

A board 300 having a multilayer electronic component embedded therein may further include a through-via 330 penetrating the core layer 310. The through-via 330 may perform various functions depending on the design. For example, the through-via 330 may include a ground via, a power via, a signal via, and the like. The through-via 330 may include an electrolytically plated layer, an electroless plated layer, and/or a sputtered layer.

The board 300 having a multilayer electronic component embedded therein may further include a build-up layer disposed on the upper and lower sides of the core layer 310. For example, a board 300 having a multilayer electronic component embedded therein may further include one or more first build-up insulating layers 341 disposed on the upper surface of the core layer 310, one or more first build-up wiring layers 342 respectively disposed on or within the one or more first build-up insulating layers 341, one or more first build-up via layers 343 respectively penetrating at least one of the one or more first build-up insulating layers 341, one or more second build-up insulating layers 351 disposed on the lower surface of the core layer 310, one or more second build-up wiring layers 352 respectively disposed on or within the one or more second build-up insulating layers 351, one or more second build-up via layers 353 respectively penetrating at least one of the one or more second build-up insulating layers 351, a first resist layer 361 disposed on an uppermost first build-up insulating layer 341 among the one or more first build-up insulating layers 341, and a second resist layer 362 disposed on a lowermost second build-up insulating layer 351 among the one or more second build-up insulating layers 351.

Each of the first and second build-up insulating layers 341 and 351 may include an insulating material. The insulating material may include a thermosetting resin such as an epoxy resin, a thermoplastic resin such as a polyimide, or a material including these resins together with inorganic fillers, organic fillers, and/or glass fiber (glass cloth, glass fabric). For example, the insulating material may be a non-photosensitive insulating material such as Ajinomoto Build-up Film (ABF) or Prepreg (PPG), but is not limited thereto, and other polymeric materials may also be used. Furthermore, the insulating material may be a photosensitive insulating material such as Photo Imageable Dielectric (PID). The first and second build-up insulating layers 341 and 351 of one or more layers may include substantially the same insulating material or different insulating materials.

The first and second build-up wiring layers 342 and 352 of one or more layers may include copper (Cu), aluminum (Al), silver (Ag), tin (Sn), gold (Au), nickel (Ni), lead (Pb), titanium (Ti), and/or alloys thereof. The first and second build-up wiring layers 342 and 352 may include, but are not limited to, copper (Cu). The first and second build-up wiring layers 342 and 352 of one or more layers may respectively perform various functions depending on the design, and for example, may include signal patterns, power patterns, ground patterns, and the like. These patterns may respectively have various shapes, such as lines, planes, and pads. The first and second build-up wiring layers 342 and 352 with one or more layers may each include an electroless plating layer, an electrolytic plating layer, and/or a sputtering layer, but the present disclosure is not limited thereto.

The first and second build-up via layers 343 and 353 may include copper (Cu), aluminum (Al), silver (Ag), tin (Sn), gold (Au), nickel (Ni), lead (Pb), titanium (Ti), and/or alloys thereof. The first and second build-up via layers 343 and 353 may include copper (Cu), but are not limited thereto. The first and second build-up via layers 343 and 353 with one or more layers may each include a filled VIA that fills a via hole, but may also include a conformal VIA that is disposed along the wall of the via hole. The first and second build-up via layers 343 and 353 with one or more layers may perform various functions depending on the design, and for example, may include a ground via, a power via, a signal via, and the like. The first and second build-up via layers 343 and 353 of one or more layers may have tapered shapes in opposite directions in cross-sections. The one or more first and second build-up via layers 343 and 353 may respectively include an electroless plating layer, an electrolytic plating layer, and/or a sputtering layer, but the present disclosure is not limited thereto.

The first and second resist layers 361 and 362 may include, but are not limited to, a liquid or film type solder resist, and other types of insulating materials may be used. The first and second resist layers 361 and 362 may have first and second openings, respectively, for exposing a pattern. A surface treatment layer may be formed on the pattern exposed through the first opening and/or the second opening, as necessary. Alternatively, a metal bump may be formed on the pattern exposed through the first opening and/or the second opening.

As set forth above, according to an embodiment, a multilayer electronic component that is small in volume and has excellent stability when mounted on a substrate is provided.

The present disclosure is not limited by the above-described embodiments and accompanying drawings, but is intended to be limited by the appended claims. Therefore, various forms of substitution, modification and change will be possible by those skilled in the art within the scope of the technical spirit of the present disclosure described in the claims, and this will also be said to fall within the scope of the present disclosure.

In addition, the expression ‘an embodiment’ does not indicate the same embodiment, and is provided to emphasize and describe different unique characteristics. However, the embodiments presented above are not excluded from being implemented in combination with features of another embodiment. For example, even if a matter described in one specific embodiment is not described in another embodiment, it may be understood as a description related to another embodiment, unless there is a description to the contrary or contradicting the matter in another embodiment.

In the present disclosure, the term “connected” includes not only direct connection but also indirect connection through an adhesive layer or the like. Furthermore, the term “electrically connected” includes both physically connected and unconnected cases. In addition, expressions such as first and second are used to distinguish one component from another, and do not limit the order and/or importance of the components. In some cases, without departing from the scope of rights, a first element may be named a second element, and similarly, a second element may be named a first element.

While example embodiments have been illustrated and described above, it will be apparent to those skilled in the art that modifications and variations could be made without departing from the scope of the present disclosure as defined by the appended claims.

What is claimed is:

1. A multilayer electronic component comprising:
a body including a first surface and a second surface, opposing each other in a thickness direction, a third surface and a fourth surface connected to the first and second surfaces and opposing each other in a length direction, and a fifth surface and a sixth surface connected to the first to fourth surfaces and opposing each other in a width direction, the body including a dielectric layer and a plurality of internal electrodes alternately disposed with the dielectric layer in the width direction, the plurality of internal electrodes each including a main portion and a lead-out portion extending from the main portion and exposed to the first surface;
a slot disposed on the first surface and extending in the width direction; and
a connection electrode disposed within the slot and connected to a plurality of lead-out portions.

2. The multilayer electronic component of claim 1, wherein the slot includes an empty space therein extending in the width direction and exposed to the first surface.

3. The multilayer electronic component of claim 1, wherein the slot extends between opposite side ends of the plurality of lead-out portions in the length direction, and
the plurality of lead-out portions each has a plurality of exposed ends divided from each other by the slot.

4. The multilayer electronic component of claim 1, wherein the slot includes two side surfaces opposing each other in the length direction and a bottom surface connecting the two side surfaces, and
the connection electrode is continuously disposed on the two side surfaces and the bottom surface.

5. The multilayer electronic component of claim 1, wherein the connection electrode includes a nickel (Ni) electrode layer in contact with the plurality of lead-out portions and a tin (Sn) electrode layer disposed on the nickel (Ni) electrode layer.

6. The multilayer electronic component of claim 1, wherein the connection electrode includes a conductive pillar filling a portion of the slot and a conductive joint disposed between the conductive pillar and the first surface.

7. The multilayer electronic component of claim 6, wherein the conductive pillar and a bottom surface of the slot are provided with a seed layer disposed therebetween.

8. The multilayer electronic component of claim 6, wherein the conductive pillar includes copper (Cu), and
the conductive joint includes tin (Sn).

9. The multilayer electronic component of claim 1, wherein the slot is disposed spaced apart from the fifth and sixth surfaces.

10. The multilayer electronic component of claim 1, wherein a size of the slot is smaller than a size of the plurality of lead-out portions, in the length direction, and
a size of the slot is smaller than a size of the plurality of lead-out portions, in the thickness direction.

11. The multilayer electronic component of claim 1, wherein a size of the plurality of lead-out portions is smaller than a size of the main portion, in the length direction.

12. A multilayer electronic component comprising:
a body including a first surface and a second surface, opposing each other in a thickness direction, a third surface and a fourth surface connected to the first and second surfaces and opposing each other in a length direction, and a fifth surface and a sixth surface connected to the first to fourth surfaces and opposing each other in a width direction, the body being provided with a slot disposed on the first surface and extending in the width direction; and
a connection electrode disposed within the slot,
wherein the body includes a dielectric layer and a plurality of internal electrodes alternately disposed with the dielectric layer in the width direction, and
the plurality of internal electrodes includes a main portion and a lead-out portion extending from the main portion and exposed to an inner wall of the slot and in contact with the connection electrode.

13. The multilayer electronic component of claim 12, wherein the slot includes an empty space therein extending in the width direction and exposed to the first surface.

14. The multilayer electronic component of claim 12, wherein the slot extends between opposite side ends of the lead-out portion in the length direction, and
the lead-out portion has a plurality of exposed ends divided from each other by the slot.

15. The multilayer electronic component of claim 12, wherein the slot includes two side surfaces opposing each other in the length direction and a bottom surface connecting the two side surfaces, and
the lead-out portion is exposed to the two side surfaces and the bottom surface of the slot.

16. A mounting board of a multilayer electronic component, comprising:
a printed circuit board including an electrode pad;
a connection post positioned on the electrode pad; and
the multilayer electronic component of claim 1 connected to the electrode pad,
wherein the connection post is positioned within the slot.
